(19) United States
(12) Patent Application Publication
(10) Pub. No.: US 2024/0096665 A1
(43) Pub. Date: Mar. 21, 2024

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Shinichiro MORI, Toyama (JP)

(21) Appl. No.: 18/463,529

(22) Filed: Sep. 8, 2023

(30) Foreign Application Priority Data
Sep. 21, 2022 (JP) 2022-150724

(51) Int. Cl. H01L 21/67; G11B 27/031; G11B 27/34

(52) U.S. Cl. CPC H01L 21/67253; G11B 27/031; G11B 27/34; H01L 21/67248

(57) ABSTRACT

According to the present disclosure, there is provided a technique capable of efficiently editing the file of the setting values while ensuring their consistency before and after change. There is provided a technique that includes: a display for a file describing processing conditions containing setting values; an operation controller for editing the file and undoing or redoing a setting value set in the editing; a controller for controlling an editing for the setting value and including: a memory storing the file and operation history information on the undo operation or the redo operation; and a determinator configured to determine whether or not the setting value is within an effective range when the setting value is reset during the undo operation or the redo operation; and a process vessel in which a substrate is processed based on the file stored in the memory.

### CROSS REFERENCE TO RELATED APPLICATIONS

This application claims foreign priority under 35 U.S.C. § 119(a)-(d) to Application No. JP 2022-150724 filed on Sep. 21, 2022, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

In a substrate processing apparatus, a recipe (in which process conditions for executing a substrate processing is capable of being set at each step) may be edited, or parameters for executing the recipe may be edited. In addition, each of the recipe and the parameters may include a lot of setting items. In such a case, when editing the recipe or the parameters, a heavy burden may be imposed on an editor of the recipe or the parameters. In order to reduce the burden, the substrate processing apparatus may be provided with an auxiliary function (assistance function) for editing the recipe and the parameters.

For example, according to some related arts, the substrate processing apparatus is capable of restricting an input value (which is a setting value that can be input) to an appropriate range when changing an existing value (which is a setting value already exists in the recipe or the parameters) in editing the parameters used for a recipe editing. Hereinafter, the input value and the existing value may also be collectively or individually referred to as the “setting value”. According to some related arts, an input assistance function may also be used when a file is being edited in the substrate processing apparatus.

For example, when returning to a previous state after changing the setting value a plurality of times, the file (which is edited) may be closed without saving (or storing) and an original setting value may be set again after reopening the file (which is not saved). Alternatively, the setting value (which is changed) may be manually restored to the original setting value. In such a case, the work efficiency may decrease.

In addition, when the setting value is changed, the setting value after the change may exceed not only the appropriate range (effective range) thereof but also an effective range of another setting value related thereto. As a result, it may not be possible to ensure a consistency of the setting values before and after the change.

### SUMMARY

According to the present disclosure, there is provided a technique capable of efficiently performing an editing operation for a file while ensuring a consistency of setting values before and after a change.

According to one embodiment of the present disclosure, there is provided a technique that includes: a display configured to display a file describing substrate processing conditions containing a plurality of setting values; an operation controller configured to perform an editing operation for the file and to perform at least one operation of an undo operation or a redo operation for a setting value among the plurality of setting values, wherein the setting value is set in the editing operation; a controller configured to be capable of controlling an editing operation for the setting value, wherein the controller includes: a memory configured to store the file and operation history information on the undo operation or the redo operation; and a determinator configured to determine whether or not the setting value is within an effective range when the setting value is reset during the undo operation or the redo operation; and a process vessel in which a substrate is processed based on the file stored in the memory.

### BRIEF DESCRIPTION OF THE DRAWINGS

FIG. 1 is a diagram schematically illustrating a perspective view of an example of a substrate processing apparatus according to one or more embodiments of the present disclosure.

FIG. 2 is a diagram schematically illustrating a cross-section of the substrate processing apparatus according to the embodiments of the present disclosure when viewed from side.

FIG. 3 is a block diagram schematically illustrating an example of a functional configuration of a controller of the substrate processing apparatus according to the embodiments of the present disclosure.

FIG. 4A is a diagram schematically illustrating an example of a recipe edit screen according to the embodiments of the present disclosure.

FIG. 4B is a diagram schematically illustrating another example of the recipe edit screen according to the embodiments of the present disclosure.

FIG. 4C is a diagram schematically illustrating still another example of the recipe edit screen according to the embodiments of the present disclosure.

FIG. 5 is a diagram schematically illustrating an example of an undo data storage table for an undo operation and an example of a redo data storage table for a redo operation, which are used as operation history information.

FIG. 6A is a diagram schematically illustrating a transition example of the undo data storage table and the redo data storage table when a setting operation for setting values is performed three times.

FIG. 6B is a diagram schematically illustrating an example of changes of screen setting value information and an example of changes of a display state of an undo button and a redo button in accordance with the transition example of the undo data storage table and the redo data storage table shown in FIG. 6A.

FIG. 7A is a diagram schematically illustrating a transition example of the undo data storage table and the redo data storage table when the undo operation is performed once after the setting operation for the setting values is performed twice.

FIG. 7B is a diagram schematically illustrating an example of the changes of the screen setting value information and an example of the changes of the display state of the undo button and the redo button in accordance with the transition example of the undo data storage table and the redo data storage table shown in FIG. 7A.

FIG. 8A is a diagram schematically illustrating a transition example of the undo data storage table and the redo data storage table when the undo operation is performed twice after the setting operation for the setting values is performed twice.

FIG. 8B is a diagram schematically illustrating an example of the changes of the screen setting value information and an example of the changes of the display state of the undo button and the redo button in accordance with the transition example of the undo data storage table and the redo data storage table shown in FIG. 8A.

FIG. 9A is a diagram schematically illustrating a transition example of the undo data storage table and the redo data storage table when the redo operation is further performed twice following the transition example of FIG. 8A.

FIG. 9B is a diagram schematically illustrating an example of the changes of the screen setting value information and an example of the changes of the display state of the undo button and the redo button in accordance with the transition example of the undo data storage table and the redo data storage table shown in FIG. 9A.

FIG. 10A is a diagram schematically illustrating a transition example of the undo data storage table and the redo data storage table when the setting operation for the setting values is performed twice, the undo operation is performed once and then the setting operation for the setting values is further performed once.

FIG. 10B is a diagram schematically illustrating an example of the changes of the screen setting value information and an example of the changes of the display state of the undo button and the redo button in accordance with the transition example of the undo data storage table and the redo data storage table shown in FIG. 10A.

FIG. 11 is a sequence diagram schematically illustrating an example of an edit starting process according to the embodiments of the present disclosure.

FIG. 12 is a sequence diagram schematically illustrating an example of a setting value changing process according to the embodiments of the present disclosure.

FIG. 13 is a flow chart schematically illustrating an exemplary process flow of an undo operation process according to the embodiments of the present disclosure.

FIG. 14 is a flow chart schematically illustrating an exemplary process flow of a redo operation process according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail with reference to the drawings. Like reference numerals represent like components or processes with the same actions or functions in the drawings, and redundant descriptions related thereto will be omitted. Further, the technique of the present disclosure is not limited to the following embodiments, and may be implemented with appropriate modifications within the scope of the technique of the present disclosure. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

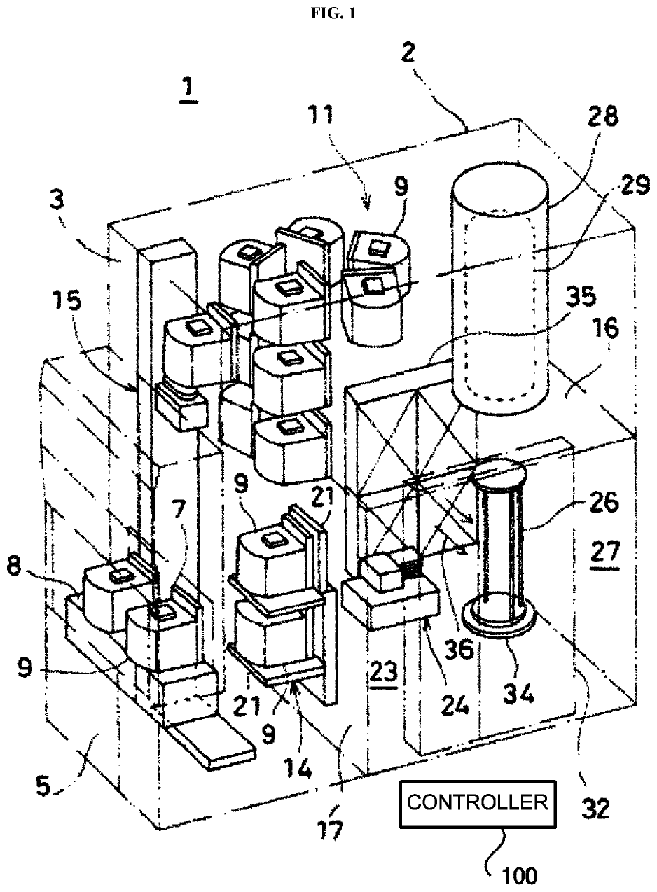

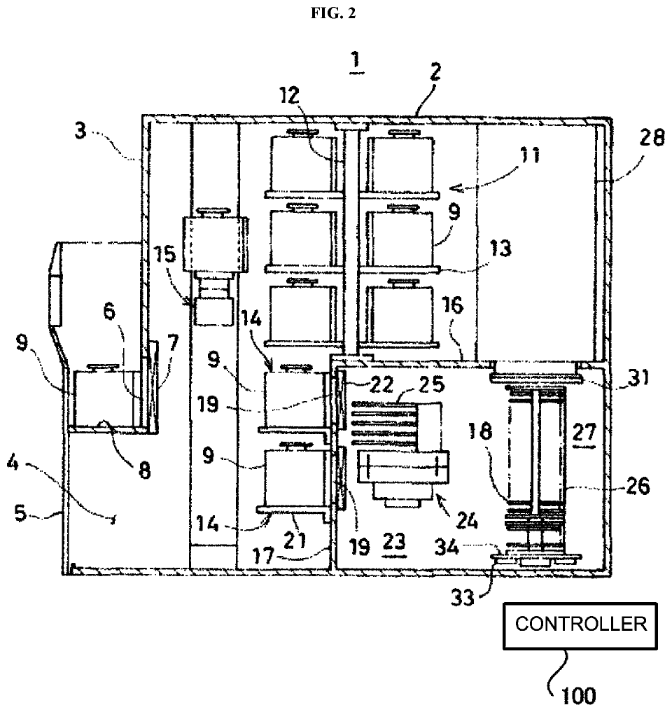

First, with reference to FIGS. 1 and 2, an outline of a substrate processing apparatus 1 according to the present embodiments will be described.

FIG. 1 is a diagram schematically illustrating a perspective view of an example of the substrate processing apparatus 1 according to the present embodiments, and FIG. 2 is a diagram schematically illustrating a cross-section of the substrate processing apparatus 1 according to the present embodiments when viewed from side. In FIGS. 1 and 2, a vertical type substrate processing apparatus is shown as an example of the substrate processing apparatus 1, and a semiconductor wafer made of a material such as silicon is shown as an example of a substrate (that is, a wafer 18) to be processed in the substrate processing apparatus 1.

As shown in FIGS. 1 and 2, the substrate processing apparatus 1 includes a housing 2. A front maintenance port 4 serving as an opening provided for maintenance is provided at a lower portion of a front wall 3 of the housing 2. The front maintenance port 4 may be opened or closed by a front maintenance door 5.

A pod loading/unloading port 6 is provided at the front wall 3 of the housing 2 so as to communicate with an inside and an outside of the housing 2. The pod loading/unloading port 6 may be opened or closed by a front shutter (which is a pod loading/unloading port opening/closing structure) 7. A loading port (which is a loading port shelf, that is, a transfer table for a substrate transfer container) 8 is provided in front of the pod loading/unloading port 6. The loading port 8 is configured such that a pod 9 is aligned while placed on the loading port 8.

For example, the pod 9 is configured as a sealed type substrate transfer container. The pod 9 may be transferred (or loaded) into and placed on the loading port 8 by an in-process transfer apparatus (not shown) and transferred (unloaded) out of the loading port 8 by the in-process transfer apparatus.

A rotatable pod shelf (which is a storage shelf for the substrate transfer container) 11 is provided in the housing 2 to be located over a substantially center portion of the housing 2 in a front-rear direction. The rotatable pod shelf 11 is configured such that a plurality of pods including the pod 9 can be stored (or placed) on the rotatable pod shelf 11. Hereinafter, the plurality of pods including the pod 9 may also be simply referred to as “pods 9”.

The rotatable pod shelf 11 includes a vertical support column 12 capable of rotating intermittently and a plurality of shelf plates (which are placing shelves for the substrate transfer container) 13. The plurality of shelf plates 13 are configured to be supported (or fixed) radially by the vertical support column 12 at positions of an upper portion, a lower portion and a mid portion of the vertical support column 12. Each of the plurality of shelf plates 13 is configured to accommodate the pod 9 when the pod 9 is placed thereon.

A pod opener (which is a structure capable of opening and closing a lid of the substrate transfer container) 14 is provided below the rotatable pod shelf 11. The pod opener 14 is provided with a configuration on which the pod 9 is placed and capable of opening and closing a lid of the pod 9.

A pod transfer structure (which is a container transfer structure) 15 is provided among the loading port 8, the rotatable pod shelf 11 and the pod opener 14. The pod transfer structure 15 is configured such that the pod 9 is capable of being elevated and lowered and being moved forward and backward in a horizontal direction while being supported by the pod transfer structure 15, and such that the pod 9 is capable of being transferred among the loading port 8, the rotatable pod shelf 11 and the pod opener 14.

A sub-housing 16 is provided below the substantially center portion of the housing 2 in the front-rear direction toward a rear end of the substrate processing apparatus 1. A pair of wafer loading/unloading ports (wafer loading/unloading ports) 19 configured to load or unload the wafer 18 serving as the substrate into or out of the sub-housing 16 is provided at a front wall 17 of the sub-housing 16. The pair of wafer loading/unloading ports 19 is arranged vertically in two stages. A pair of pod openers including the pod opener 14 are provided at the pair of wafer loading/unloading ports 19, respectively. For example, an upper pod opener and a lower pod opener may be provided as the pair of pod openers. The upper pod opener and the lower pod opener may be collectively or individually referred to as the “pod opener 14”.

The pod opener 14 may include: a placement table 21 where the pod 9 is placed thereon; and an attaching/detaching structure 22 capable of attaching and detaching the lid of the pod 9. The pod opener 14 is configured such that a wafer entrance of the pod 9 is opened or closed by detaching or attaching the lid of the pod 9 placed on the placement table 21 by the attaching/detaching structure 22.

The sub-housing 16 defines a transfer chamber 23 fluidically isolated from a space (hereinafter, also referred to as a “pod transfer space”) in which the pod transfer structure 15 or the rotatable pod shelf 11 is provided. A wafer transfer structure (substrate transfer structure) 24 is provided at a front region of the transfer chamber 23. The wafer transfer structure 24 may include a predetermined number of wafer mounting plates (for example, as shown in FIG. 2, five wafer mounting plates) 25 on which a predetermined number of wafers including the wafer 18 are placed. Each of the wafer mounting plates 25 is capable of being moved directly in the horizontal direction, being rotated in the horizontal direction and being elevated or lowered in a vertical direction. The wafer transfer structure 24 is configured such that the wafer 18 is capable of being loaded into or unloaded out of a boat (which is a substrate retainer) 26.

In a rear region of the transfer chamber 23, a standby space 27 where the boat 26 is accommodated and in standby is provided, and a process furnace 28 such as a vertical type process furnace is provided above the standby space 27. A process chamber 29 is provided inside the process furnace 28, and a lower end portion of the process chamber 29 is configured as a furnace opening. The furnace opening is opened or closed by a furnace opening shutter (which is a furnace opening opening/closing structure) 31. The process furnace 28 serves as an example of a process vessel.

A boat elevator (which is a substrate retainer elevating structure) 32 capable of elevating and lowering the boat 26 is provided between a right end of the housing 2 and a right end of the standby space 27 of the sub-housing 16. A seal cap 34 serving as a lid is horizontally attached to an arm 33 connected to an elevating platform of the boat elevator 32. The seal cap 34 is configured such that the boat 26 can be vertically supported by the seal cap 34, and such that the furnace opening can be airtightly closed by the seal cap 34 while the boat 26 is loaded into the process chamber 29.

The boat 26 is configured such that a plurality of wafers including the wafer 18 are supported on the boat 26 in a horizontal orientation in a multistage manner with their centers aligned with one another. Hereinafter, the plurality of wafers including the wafer 18 may also be simply referred to as “wafers 18”.

A clean air supplier (which is a clean air supply structure) 35 is arranged at a position facing the boat elevator 32. The clean air supply supplier 35 is constituted by a supply fan and a dustproof filter so as to supply clean air 36 such as an inert gas and a clean atmosphere. As the inert gas, for example, a nitrogen (N)-containing gas may be used. As the nitrogen-containing gas, for example, a gas such as nitrogen (N2) gas and ammonia (NH3) gas may be used. As the nitrogen-containing gas, for example, one or more of the gases exemplified above may be used. A notch alignment device (not shown) serving as a substrate alignment device configured to align a circumferential position of the wafer 18 is provided between the wafer transfer structure 24 and the clean air supplier 35.

The clean air 36 ejected from the clean air supplier 35 is circulated in components such as the notch alignment device (not shown), the wafer transfer structure 24 and the boat 26. Thereafter, the clean air 36 is exhausted out of the housing 2 through a duct (not shown), or is ejected again into the transfer chamber 23 by the clean air supplier 35.

Subsequently, an operation of the substrate processing apparatus 1 will be described.

When the pod 9 is supplied to the loading port 8, the pod loading/unloading port 6 is opened by the front shutter 7. Then, the pod 9 placed on the loading port 8 is transferred (loaded) into the housing 2 through the pod loading/unloading port 6 by the pod transfer structure 15, and is placed on a designated shelf plate among the plurality of shelf plates 13 of the rotatable pod shelf 11. The pod 9 is temporarily stored in the rotatable pod shelf 11. Then, the pod 9 is transferred from the designated shelf plate among the plurality of shelf plates 13 to the placement table 21 of the pod opener 14 (that is, one of the upper pod opener and the lower pod opener) by the pod transfer structure 15. Alternatively, the pod 9 may be transferred directly from the loading port 8 to the placement table 21 of the pod opener 14.

When the pod 9 is being transferred, the wafer loading/unloading ports 19 are closed by the attaching/detaching structure 22, and the transfer chamber 23 is filled with the clean air 36. For example, the transfer chamber 23 is filled with the nitrogen-containing gas serving as the clean air 36 such that an oxygen concentration in the transfer chamber 23 is set to 20 ppm or less, which is much lower than an oxygen concentration in the housing 2 (which is an atmospheric atmosphere).

When an end surface of the pod 9 placed on the placement table 21 is pressed against an opening edge of one of the pair of wafer loading/unloading ports 19 of the front wall 17 of the sub-housing 16, the attaching/detaching structure 22 detaches the lid of the pod 9 and the wafer entrance of the pod 9 is opened.

When the pod 9 is opened by the pod opener 14 (that is, one of the upper pod opener and the lower pod opener), the wafer 18 is then taken out from the pod 9 by the wafer transfer structure 24, transferred to the notch alignment device (not shown), and aligned by the notch alignment device. Then, by the wafer transfer structure 24, the wafer 18 is transferred (or loaded) into the standby space 27 provided in the rear region of the transfer chamber 23, and loaded (or charged) into the boat 26.

After the wafer 18 is charged into the boat 26, the wafer transfer structure 24 then returns to the pod 9 and transfers a next wafer among the wafers 18 from the pod 9 into the boat 26.

While the wafer transfer structure 24 loads the wafers 18 into the boat 26 through the pod opener 14 (which is one of the upper pod opener and the lower pod opener), another pod 9 is transferred from the rotatable pod shelf 11 by the pod transfer structure 15 to the pod opener 14 (which is the other one of the upper pod opener and the lower pod opener), and the lid of the aforementioned another pod 9 is opened by the other one of the upper pod opener and the lower pod opener.

When a predetermined number of wafers including the wafer 18 are charged into the boat 26, the furnace opening of the process furnace 28 closed by the furnace opening shutter 31 is opened by the furnace opening shutter 31. Subsequently, the boat 26 accommodating the wafers 18 is elevated by the boat elevator 32 such that the boat 26 is loaded (inserted) into the process chamber 29.

After the boat 26 is loaded, the furnace opening is airtightly closed by the seal cap 34. Further, according to the present embodiments, at this timing (that is, after the boat 26 is loaded), a purge step (also referred to as a “pre-purge step”) of replacing an inner atmosphere of the process chamber 29 with the inert gas is performed.

The process chamber 29 is vacuum-exhausted by a gas exhaust structure (which is a gas exhauster) (not shown) such that an inner pressure of the process chamber 29 reaches and is maintained at a desired pressure (vacuum degree). Further, the process chamber 29 is heated to a predetermined temperature by a heater driver (not shown) such that a desired temperature distribution of the process chamber 29 is obtained.

Further, a process gas whose flow rate is controlled to a predetermined flow rate is supplied by a gas supply structure (which is a gas supplier) (not shown), and the process gas comes into contact with a surface of the wafer 18 while flowing through the process chamber 29. Thereby, a predetermined processing such as a substrate processing described later is performed on the surface of the wafer 18. Further, the process gas after a reaction of the predetermined processing is exhausted from the process chamber 29 by the gas exhaust structure. In the present specification, the “process gas” refers to a gas supplied into the process chamber 29. The same also applies to the following description.

After a predetermined process time has elapsed, the inert gas is supplied from an inert gas supply source (not shown) by the gas supply structure, the inner atmosphere of the process chamber 29 is replaced with the inert gas, and the inner pressure of the process chamber 29 is returned to the normal pressure (after-purge step). Then, the boat 26 is lowered by the boat elevator 32 through the seal cap 34. In the present specification, the “process time” refers to a time duration of continuously performing a process related thereto. The same also applies to the following description.

After the wafer 18 is processed, the wafer 18 and the pod 9 are transferred (unloaded) out of the housing 2 in an order reverse to that of loading the wafer 18 and the pod 9 into the housing 2 described above. Then, an unprocessed wafer 18 is further loaded into the boat 26, and a batch processing of the wafer 18 is repeatedly performed.

According to the present embodiments, as shown in FIGS. 1 and 2, the substrate processing apparatus 1 includes a controller 100, and the controller 100 is configured to control the substrate processing apparatus 1. The controller 100 may be provided (embedded) in the substrate processing apparatus 1, or may be provided outside the substrate processing apparatus 1 so as to be accessible.

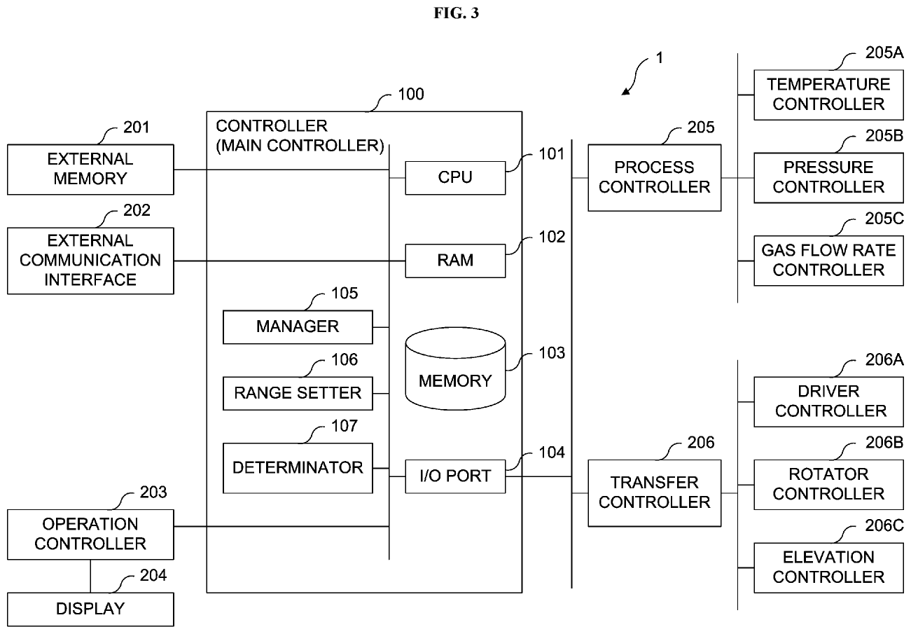

Subsequently, with reference to FIG. 3, a configuration of a control system of the substrate processing apparatus 1 according to the present embodiments will be described.

FIG. 3 is a block diagram schematically illustrating an example of a functional configuration of the controller 100 of the substrate processing apparatus 1 according to the present embodiments.

As shown in FIG. 3, the substrate processing apparatus 1 includes the controller (which is a main controller) 100, an external memory 201, an external communication interface 202, an operation controller 203, a display (which is a display structure) 204, a process controller 205 and a transfer controller 206.

Further, the controller 100 includes a CPU (Central Processing Unit) 101, a RAM (Random Access Memory) 102, a memory 103, an I/O port (input/output port) 104, a manager (which is a managing structure) 105, a range setter (which is a range setting structure) 106 and a determinator (which is determination structure) 107.

The controller 100 is connected to the operation controller 203 and is also connected to the process controller 205 and the transfer controller 206 via the I/O port 104. Since the controller 100 is electrically connected to each of the process controller 205 and the transfer controller 206 via the I/O port 104, each data can be transmitted or received and each file can be uploaded or downloaded among the controller 100, the process controller 210 and the transfer controller 230.

For example, the controller 100 is provided with the external memory 201 serving as a mounting structure where a recording medium such as a USB (Universal Serial Bus) memory is installed or removed. Further, for example, the controller 100 is connected to an external host computer (not shown) via an external communication interface 229. Therefore, even when the substrate processing apparatus 1 is installed in a clean room, the external host computer can be arranged in a location such as an office outside the clean room.

The operation controller 203 and the display 204 may be implemented as an integrated structure, or the operation controller 203 may be connected to the display 204 via a connector such as a video cable. For example, the display 204 is constituted by a liquid crystal display panel. The display 204 is configured to display each operation screen for operating the substrate processing apparatus 1. The operation screen may include a screen for confirming a state of a substrate process system controlled by the process controller 205 or a state of a substrate transfer system controlled by the transfer controller 206. For example, on the operation screen of the display 204, operation buttons serving as an input structure through which an operation instruction to the substrate transfer system or the substrate processing system is input may be provided. The operation controller 203 is configured to display information generated in the substrate processing apparatus 1 via the operation screen of the display 204. Further, for example, the operation controller 203 is configured to output the information displayed on the display 204 to a component such as the USB memory inserted in the external memory 201. The operation controller 203 is configured to accept (receive) input data (input instruction) from the operation screen displayed on the display 204 and is further configured to transmit the input data to the controller 100. Further, the operation controller 203 is configured to accept (receive) an instruction (control instruction) for executing a recipe stored in the RAM 102 or an appropriate substrate processing recipe (also referred to as a “process recipe”) among a plurality of recipes stored in the memory 103, and is further configured to transmit the instruction (control instruction) to the controller 100. For example, the operation controller 203 and the display 204 may be constituted by a touch panel. Although the operation controller 203 and the display 204 are provided separately from the controller 100, the controller 100, the operation controller 203 and the display 204 may be implemented as an integrated structure.

The process controller 205 may include a temperature controller 205A, a pressure controller 205B and a gas flow rate controller 205C. The temperature controller 205A, the pressure controller 205B and the gas flow rate controller 205C described above constitute sub-controllers, and are electrically connected to the process controller 205. Therefore, each data can be transmitted or received and each file can be uploaded or downloaded among the process controller 205, the temperature controller 205A, the pressure controller 205B and the gas flow rate controller 205C. Although the process controller 205 and the sub-controllers thereof (that is, the temperature controller 205A, the pressure controller 205B and the gas flow rate controller 205C) are shown separately, the process controller 205 and the sub-controllers thereof may be implemented as an integrated structure.

For example, a heating structure constituted mainly by a heater (not shown) and a temperature sensor (not shown) is connected to the temperature controller 205A. The temperature controller 205A is configured to adjust an inner temperature of the process furnace 28 by controlling a temperature of the heater of the process furnace 28. Further, the temperature controller 205A is configured to control the electric power supplied to a heater wire by controlling a switching (which is an on/off control) of a thyristor.

For example, the gas exhaust structure (not shown) constituted mainly by a pressure sensor (not shown) and an APC (Automatic Pressure Control) valve (not shown) serving as a pressure valve is connected to the pressure controller 205B. The gas exhaust structure may further include a vacuum pump (not shown). The pressure controller 205B is configured to control an opening degree of the APC valve and a switching (which is an on/off control) of the vacuum pump based on a pressure value detected by the pressure sensor such that the inner pressure of the process chamber 29 reaches a desired pressure at a desired timing.

The gas flow rate controller 205C is constituted by a mass flow controller (MFC) (not shown).

The transfer controller 206 may include a driver controller 206A, a rotator controller 206B and an elevation controller 206C. The driver controller 206A is configured to control a driver system of the substrate processing apparatus 1. The rotator controller 206B is configured to control a rotating system of the substrate processing apparatus 1. The elevation controller 206C is configured to control an elevation system of the substrate processing apparatus 1. For example, the transfer controller 206 is configured to control a transfer operation of a component such as the rotatable pod shelf 11, the boat elevator 32, the pod transfer structure 15, the wafer transfer structure 24, the boat 26 and a rotator (not shown).

According to the present embodiments, each of the controller 100, the process controller 205 and the transfer controller 206 may be embodied by a general computer system instead of a dedicated computer system. For example, by installing in the general computer system a program for executing the predetermined processing described above from a predetermined recording medium such as a CD-ROM and a USB memory storing the program, each controller described above may be provided to perform the predetermined processing.

Further, a method of supplying the program can be appropriately selected. Instead of or in addition to being supplied through the predetermined recording medium as described above, for example, the program may be provided through a communication line, a communication network or a communication system.

As described above, the controller 100 may be embodied by a computer including the CPU 101, the RAM 102, the memory 103 and the I/O port 104. In the memory 222, a recipe file such as the recipe in which process conditions and process sequences of the substrate processing are defined, a control program file for executing the recipe file, a parameter file (setting value file) in which parameters for setting the process conditions and the process sequences are defined, an error processing program file, a parameter file for an error processing, various screen files including an input screen for inputting process parameters and various icon files and the like (which are not shown) are stored (or saved). For example, the controller 100 is electrically connected to a network such as the Internet, a LAN (Local Area Network) and a WAN (Wide Area Network) by using the external communication interface 202, and is configured to be capable of communicating with external apparatuses via the network.

For example, as the memory 103, a component such as a hard disk drive (HDD), a solid state drive (SSD) and a flash memory may be used. The memory 103 is configured to store a setting value editing program for executing a setting value editing process according to the present embodiments.

For example, the setting value editing program may be installed in the substrate processing apparatus 1 in advance. The setting value editing program may be recorded (stored) in a non-volatile recording medium or may be distributed via the network. Then, the setting value editing program may be installed in the substrate processing apparatus 1 as appropriate. For example, as the non-volatile recording medium, a component such as the CD-ROM, a magneto-optical disk, the HDD, a DVD-ROM, the flash memory, a memory card and the USB memory may be used.

That is, the setting value editing program may refer to a program that causes the substrate processing apparatus 1, by the computer, to perform: (a) displaying a file describing substrate processing conditions containing a plurality of setting values, (b) performing at least one operation among an undo operation (cancel operation) and a redo operation for a setting value among the plurality of setting values when editing the setting value; (c) storing the file and operation history information on the undo operation or the redo operation; and (d) determining whether or not the setting value is within an effective range when the setting value is reset during the undo operation or the redo operation.

The CPU 101 of the substrate processing apparatus 1 according to the present embodiments functions as the controller 100, the manager 105, the range setter 106 and the determinator 107 by writing the setting value editing program stored in the memory 103 to the RAM 102 and executing the setting value editing program.

As described above, the substrate processing apparatus 1 according to the present embodiments includes the display 204, the operation controller 203, the memory 103, the determinator 107, the external memory 201, the external communication interface 202 and the controller 100.

The display 204 is configured to be capable of displaying the file describing the substrate processing conditions containing the plurality of setting values.

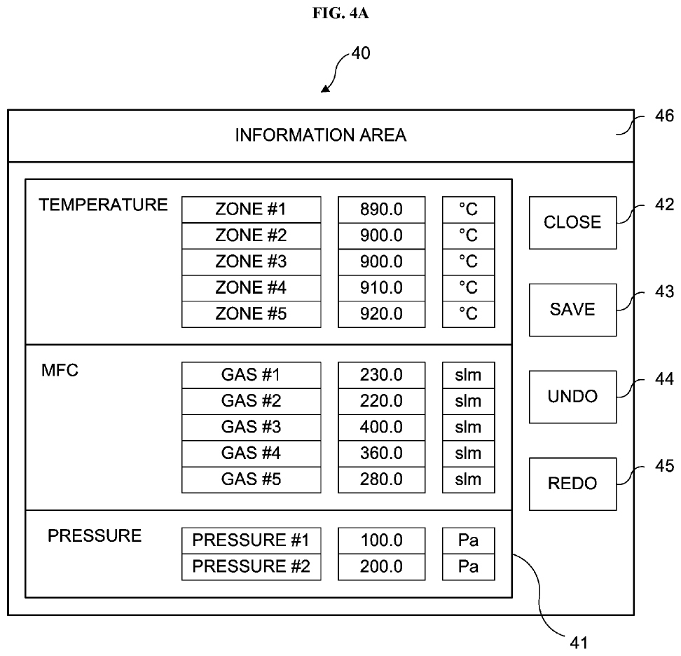

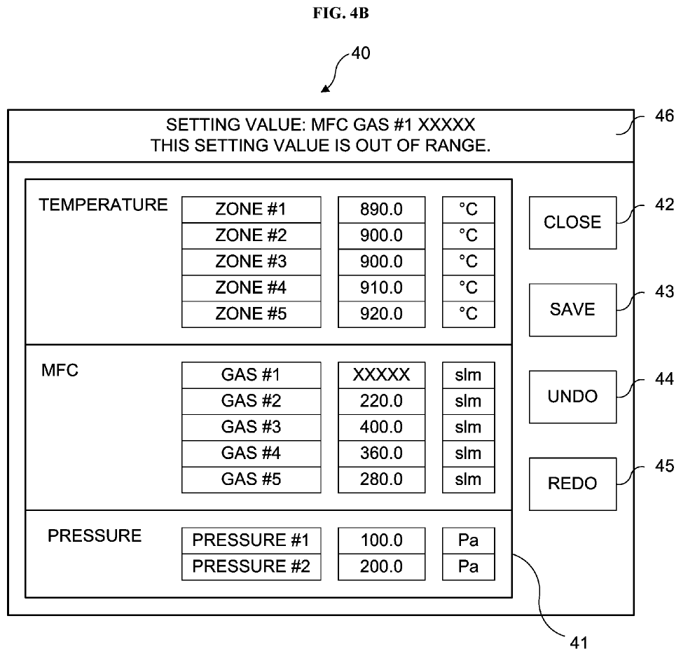

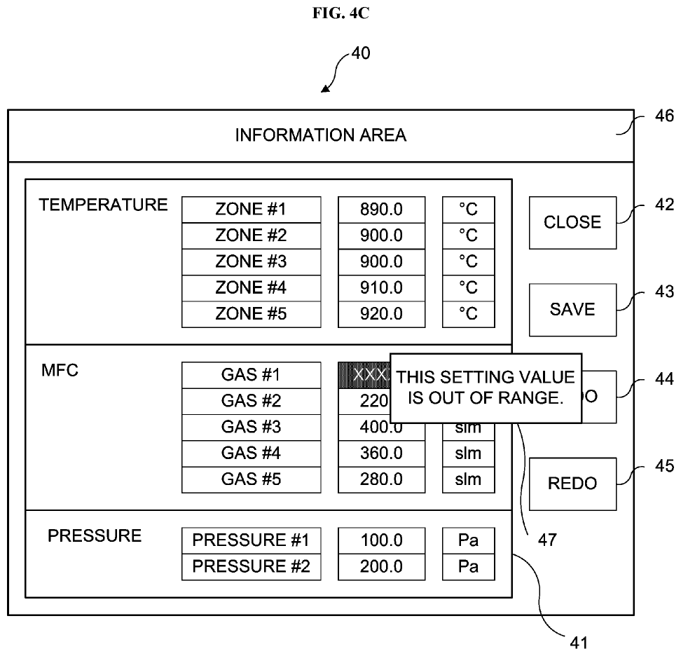

The operation controller 203 is configured to be capable of performing an editing operation for the file displayed on the display 204 and further capable of performing at least one operation among the undo operation and the redo operation for the setting value which is set in the editing operation. In the editing operation for the file, it is possible to edit the setting value of an item. In the present embodiments, for example, as shown in FIG. 4A, the display 204 displays a recipe edit screen including the file, as shown in FIG. 4A.

FIG. 4A is a diagram schematically illustrating an example of a recipe edit screen 40 according to the present embodiments.

On the recipe edit screen 40 shown in FIG. 4A, a file 41 describing the substrate processing conditions containing setting values of a temperature, a gas flow rate (MFC) and a pressure as an example of the plurality of setting values is displayed. Further, the recipe edit screen 40 may include a close button (“CLOSE” shown in FIG. 4A) 42 for closing the file 41, a save button (“SAVE” shown in FIG. 4A) 43 for saving the file 41, an undo button (cancel button) button (“UNDO” shown in FIG. 4A) 44 for canceling (undoing) the setting value set by the editing operation and returning the setting value to an original setting value, a redo button (“REDO” shown in FIG. 4A) 45 for redoing (reperforming) the setting value set by the editing operation and resetting the setting value and an information area (“INFORMATION AREA” shown in FIG. 4A) 46 serving as an area for displaying various information.

The memory 103 stores the file describing the substrate processing conditions containing the plurality of setting values, and further stores the operation history information on the undo operation or the redo operation.

The determinator 107 is configured to determine whether or not the setting value is within the effective range when the setting value is reset during the undo operation or the redo operation.

The controller 100 includes the memory 103 and the determinator 107, and is configured to be capable of controlling the editing operation for the setting value. Specifically, when the operation controller 203 instructs to perform the undo operation or the redo operation, the controller 100 controls the undo operation (cancel operation) or the redo operation for the setting value. The controller 100 instructs the determinator 107 to perform a validity check (range check) on an entirety of edit items when a confirmation operation for the setting value is performed or when the undo operation or the redo operation is performed.

According to such a configuration, by recalculating an input range and performing the range check for the entirety of the edit items when the setting value is changed, it is possible to always maintain a consistency of the edit items, and it is also possible to reduce a wasted time for re-editing the file due to a file inconsistency when executing the substrate processing. As a result, it is possible to contribute to improving a production efficiency.

In addition, by confirming the effective range for the entirety of the edit items when the edit items are set, it is possible to clarify the items to be corrected, and thereby, it is possible to contribute to an efficiency of editing the file. As a result, it is possible to contribute to improving a work efficiency.

Specifically, the controller 100 includes the manager 105 configured to manage the setting value. In accordance with an instruction from the operation controller 203, the manager 105 searches for information on the setting value instructed as described above, and returns a search result to the operation controller 203. For example, when displaying the recipe edit screen 40, the manager 105 reads file information including the setting value stored in the memory 103, and expands the file information read as described above in the RAM 102. Further, when the operation controller 203 requests a display of the item, the manager 105 searches the RAM 102 for the setting value of the item related thereto, acquires the setting value searched as described above, and returns the setting value acquired as described above to the operation controller 203. Then, the operation controller 203 passes the setting value acquired from the manager 105 to the display 204. Thereby, it is possible to easily acquire the setting value instructed as described above.

The controller 100 further includes the range setter 106 configured to set an upper limit value and a lower limit value of the effective range of the setting value. In accordance with an effective range setting instruction from the manager 105, the range setter 106 is further configured to set effective ranges of the entirety of the setting values, respectively. Specifically, the range setter 106 sets the effective ranges for the entirety of the items, respectively. Since each effective range varies depending on the conditions of each setting item, the effective ranges are set each time. Further, the effective range may be stored in advance as effective range information in the memory 103, and the effective range information may be read as appropriate to set the effective range matching the conditions. Alternatively, the effective range may be calculated in accordance with the conditions by a program. Thereby, it is possible to set the effective ranges of the entirety of the setting values, respectively.

Further, the range setter 106 checks range setting conditions set in advance for each item and setting information for another item related thereto to calculate the upper limit value and the lower limit value. For example, when a unit for a pressure setting value is “Pa”, the setting value is within a range from 0000.00 Pa to 9999.99 Pa. For example, when the unit for the pressure setting value is “Torr”, the setting value is within a range from 00.000 Torr to 99.999 Torr. Then, the effective range is changed in accordance with the relevant conditions. In the present specification, a numerical range “from 0000.00 Pa to 9999.99 Pa” indicates a range of values, and means a range equal to or higher than 0000.00 Pa and equal to or lower than 9999.99 Pa. The same also applies when defining a range other than “Pa”. For example, when a unit of the gas flow rate is “slm”, the setting value is within a range from 0000.000 slm to 9999.000 slm. For example, when the unit of the gas flow rate is “sccm”, the setting value is within a range from 00.0 sccm to 99.0 sccm. Further, when a supply flow rate (that is, the gas flow rate) is “0 slm” or “0 sccm”, it indicates a case where a substance (gas) is not supplied. The same also applies to the following description. According to the present embodiments, it is possible to appropriately calculate the upper limit value and the lower limit value of the effective range.

For example, when the setting value is changed, the determinator 107 determines whether or not the entirety of the setting values defined in the file are within the effective ranges (valid ranges) related thereto. The determinator 107 compares the setting value of the setting information designated by the manager 105 and the effective range which is set by the range setter 106, and determines whether or not the setting value is within the effective range. Then, the determinator 107 returns a determined result to the manager 105. Thereby, it is possible to determine whether or not the entirety of the setting values defined in the file are within the effective ranges related thereto.

For example, when the determination result of the determinator 107 is that the setting value is out of the effective range, the controller 100 may notify the operation controller 203 that the setting value is out of the effective range. Thereby, it is possible to notify the operation controller 203 of the setting value out of the effective range.

In accordance with a notification from the controller 100, the operation controller 203 instructs the display 204 to display that there is the setting value out of the effective range. In such a case, in accordance with an instruction from the operation controller 203, the display 204 may display a notification that the setting value is out of the effective range or may switch a display of a target setting value (that is, the setting value to be displayed), or may display the notification that the setting value is out of the effective range and switch the display of the target setting value. For example, as shown in FIG. 4B, a message is displayed in the information area 46 positioned at an upper portion of the recipe edit screen 40 such that the item determined to be out of the effective range can be easily identified. As the message, for example, the setting value information out of the effective range and a text message indicating that the setting value is out of the effective range are displayed. By displaying the message in the information area 46, it is possible to notify the setting value that is out of the effective range on the recipe edit screen 40.

For example, as shown in FIG. 4C, a message 47 may be displayed near the item such that the item determined to be out of the effective range can be easily identified. For example, the message 47 may be displayed as a tooltip or a message box. For example, a background related thereto may be switched such that the item determined to be out of the effective range can be easily identified. In addition, a display color (character color) of the setting value may be switched. In FIG. 4C, for example, the background is switched from white to black. In an example shown in FIG. 4C, the background is black. However, an appropriate color may be used as long as it is different from the other items. For example, display characters displayed related to the item may be switched such that the item determined to be out of the effective range can be easily identified. As a result, the setting value out of the effective range can be displayed to notify a user.

According to the present embodiments, as shown in FIG. 4A described above, the display 204 is provided with the undo button 44 and the redo button 45, which are buttons for the undo operation and the redo operation, respectively. By using the buttons, it is possible to easily perform the undo operation and the redo operation. The display 204 may switch the display characters of the undo button 44 and the redo button 45 in accordance with a display language of the display 204. For example, it is possible to contribute to a file operation support by switching the display characters, for example, Japanese, English and the like, in accordance with the language designated by a delivery destination of the substrate processing apparatus 1. When Japanese is designated, “UNDO” shown in FIGS. 4A through 4C is switched to the Japanese word for “undo” and “REDO” shown in FIGS. 4A through 4C is switched to the Japanese word for “redo”.

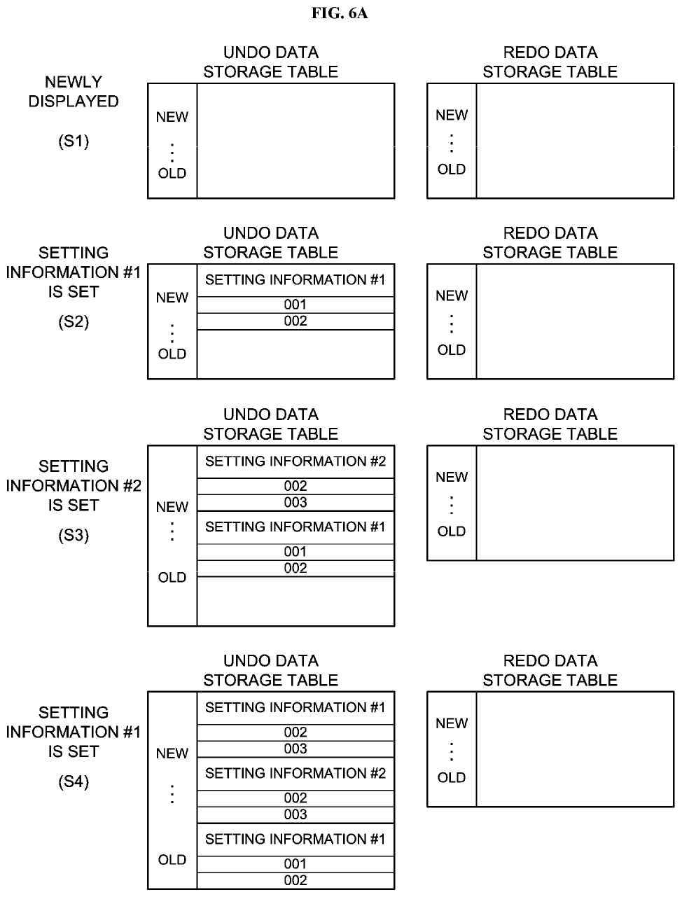

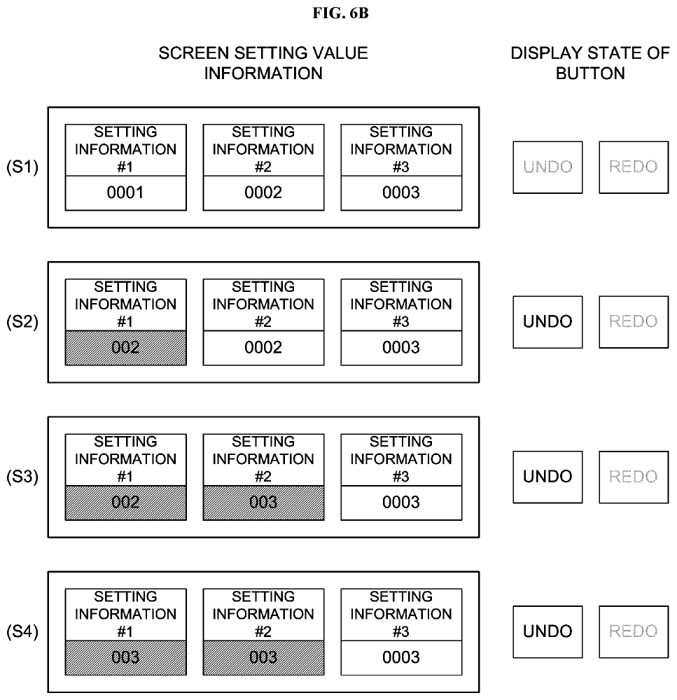

For example, the display 204 may switch a display of at least one among the undo button 44 and the redo button 45 in accordance with the undo operation or the redo operation. For example, as shown in FIGS. 6B, 7B, 8B, 9B and 10B described later, one or more unexecutable buttons among the undo button 44 and the redo button 45 may be grayed out or hidden. In such a case, whether the undo button 44 or the redo button 45 is capable of being executed can be checked (or confirmed) on the recipe edit screen 40. Thereby, it is possible to contribute to the file operation support.

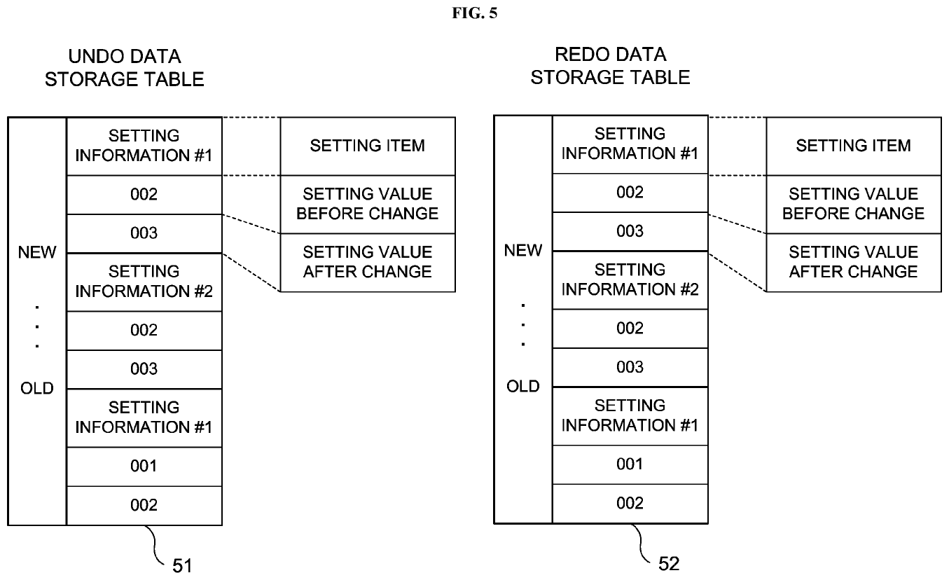

Subsequently, a transition example of the operation history information of on the undo operation or the redo operation according to the present embodiments will be specifically described with reference to FIG. 5 and FIGS. 6A through 10B.

FIG. 5 is a diagram schematically illustrating an example of an undo data storage table for the undo operation and an example of a redo data storage table for the redo operation, which are used to store the operation history information containing an operation history of the undo operation or the redo operation.

The operation history information may include undo history information 51 serving as undo operation history information and redo history information 52 serving as redo operation history information. For example, the undo history information 51 may include setting items, the setting value before a change and the setting value after the change. For example, the redo history information 52 may include the setting items, the setting value before the change and the setting value after the change.

As shown in FIG. 5, the undo data storage table for the undo operation and the redo data storage table for the redo operation may contain substantially the same table configuration. The undo data storage table serves as an example of first operation history information, and the redo data storage table serves as an example of second operation history information.

That is, the operation history information may include: the undo data storage table configured to store setting value related information of the setting value; and the redo data storage table configured to store the setting value related information serving as an undo history when the undo operation is executed. Further, the setting value related information may include at least one among the setting items, the setting value before the change and the setting value after the change. By using the data storage tables described above, it is possible to easily manage the undo operation and the redo operation, and it is also possible to contribute to a reduction of wasteful searches. Further, it is possible to shorten an operation time.

For example, when executing the undo operation (cancel operation), the controller 100 stores the setting value related information (which is stored in the undo data storage table) into the redo data storage table, and deletes the setting value related information stored in the undo data storage table.

For example, when executing the redo operation, the controller 100 stores the setting value related information (which is stored in the redo data storage table) into the undo data storage table, and deletes the setting value related information stored in the redo data storage table.

For example, when acquiring new setting value related information, the controller 100 stores the setting value related information (which is stored in the redo data storage table) into the undo data storage table, and stores the new setting value related information into the undo data storage table. In such a case, the controller 100 may clear (that is, delete) an entirety of data in the redo data storage table.

Further, the controller 100 may clear (delete) the operation history information, that is, the data in the undo data storage table and the redo data storage table when the editing operation for the file is completed.

FIG. 6A is a diagram schematically illustrating a transition example of the undo data storage table and the redo data storage table when the setting values are set three times (that is, a setting operation for the setting values is performed three times). Further, FIG. 6B is a diagram schematically illustrating an example of changes of screen setting value information and an example of changes of a display state of the undo button and the redo button in accordance with the transition example of the undo data storage table and the redo data storage table shown in FIG. 6A. Further, the data stored in the tables is input or output in accordance with a LIFO (Last In First Out) method.

In “S1” shown in FIG. 6B, as an example, the recipe edit screen 40 shown in FIG. 4A is newly displayed. In such a case, setting information #1, setting information #2 and setting information #3 are displayed as the screen setting value information shown in “S1” of FIG. 6B. In the setting information #1, “001” is displayed as the setting value before the change. In the setting information #2, “002” is displayed as the setting value before the change. In the setting information #3, “003” is displayed as the setting value before the change. As for the display state of the buttons, both of the undo button and the redo button are displayed (for example, grayed out) indicating that they cannot be executed (that is, unexecutable). In such a case, as shown in “S1” of FIG. 6A, no data is stored in each of the undo data storage table and the redo data storage table.

Subsequently, in “S2” shown in FIG. 6B, “002” is input in the setting information #1 as the setting value after the change. As the screen setting value information, “002” is displayed as the setting value after the change in the setting information #1, “002” is continuously displayed as the setting value before the change in the setting information #2, and “003” is continuously displayed as the setting value before the change in the setting information #3. For example, a display color (background color) of the setting value after the change may be switched to a background color different from that of the setting value before the change. For example, display characters of the setting value after the change may be changed by switching the display color of the display characters. For example, in FIG. 6B, the background color of the setting value after the change is gray. For example, as the display state of the buttons, an unexecutable sate of the undo button is canceled so as to indicate that the undo operation can be executed, and an unexecutable sate of the redo button is continuously displayed so as to indicate that the redo operation cannot be executed. In such a case, in “S2” of FIG. 6A, the setting value related information of the setting information #1 is stored into the undo data storage table. In such a case, the setting value related information of the setting information #1 stored in the undo data storage table includes “001” as the setting value before the change and “002” as the setting value after the change.

Subsequently, in “S3” shown in FIG. 6B, “003” is input in the setting information #2 as the setting value after the change. As the screen setting value information, “002” is continuously displayed as the setting value after the change in the setting information #1, “003” is displayed as the setting value after the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 6B, the background color of the setting value after the change is gray. For example, as the display state of the buttons, an executable state of the undo button is displayed so as to indicate that the undo operation can be executed, and the unexecutable state of the redo button is continuously displayed so as to indicate that the redo operation cannot be executed. In such a case, in “S3” of FIG. 6A, the setting information #2 is stored into the undo data storage table. In such a case, the setting information #2 stored in the undo data storage table includes “002” as the setting value before the change and “003” as the setting value after the change.

Subsequently, in “S4” shown in FIG. 6B, “003” is input in the setting information #1 as the setting value after the change. As the screen setting value information, “003” is displayed as the setting value after the change in the setting information #1, “003” is continuously displayed as the setting value after the change in the setting information #2, and “003” is continuously displayed as the setting value before the change in the setting information #3. For example, as the display state of the buttons, the executable state of the undo button is continuously displayed so as to indicate that the undo operation can be executed, and the unexecutable state of the redo button is continuously displayed so as to indicate that the redo operation cannot be executed. In such a case, in “S4” of FIG. 6A, new setting information #1 is stored into the undo data storage table. In such a case, the new setting information #1 stored in the undo data storage table includes “002” as the setting value before the change and “003” as the setting value after the change.

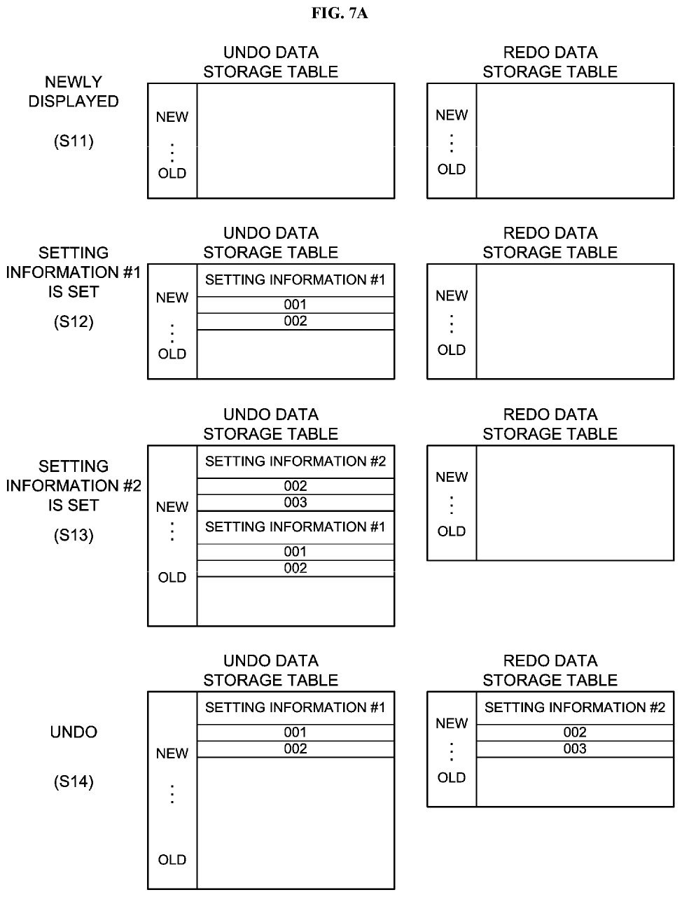

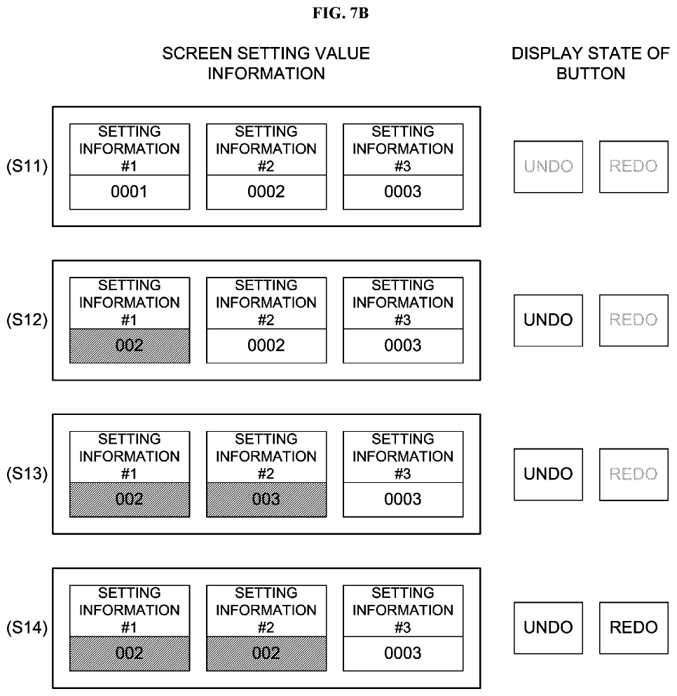

FIG. 7A is a diagram schematically illustrating a transition example of the undo data storage table and the redo data storage table when the undo operation is performed once after the setting operation for the setting values is performed twice. Further, FIG. 7B is a diagram schematically illustrating an example of the changes of the screen setting value information and an example of the changes of the display state of the undo button and the redo button in accordance with the transition example of the undo data storage table and the redo data storage table shown in FIG. 7A.

In “S11” shown in FIG. 7B, as an example, the recipe edit screen 40 shown in FIG. 4A is newly displayed. In such a case, the setting information #1, the setting information #2 and the setting information #3 are displayed as the screen setting value information shown in “S11” of FIG. 7B. In the setting information #1, “001” is displayed as the setting value before the change. In the setting information #2, “002” is displayed as the setting value before the change. In the setting information #3, “003” is displayed as the setting value before the change. As for the display state of the buttons, both of the undo button and the redo button are displayed (for example, grayed out) indicating that they cannot be executed. In such a case, as shown in “S11” of FIG. 7A, no data is stored in each of the undo data storage table and the redo data storage table.

Subsequently, in “S12” shown in FIG. 7B, “002” is input in the setting information #1 as the setting value after the change. As the screen setting value information, “002” is displayed as the setting value after the change in the setting information #1, “002” is continuously displayed as the setting value before the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 7B, the background color of the setting value after the change is gray. For example, as the display state of the buttons, the unexecutable sate of the undo button is canceled so as to indicate that the undo operation can be executed, and the unexecutable sate of the redo button is continuously displayed so as to indicate that the redo operation cannot be executed. In such a case, in “S12” of FIG. 7A, the setting value related information of the setting information #1 is stored into the undo data storage table. In such a case, the setting value related information of the setting information #1 stored in the undo data storage table includes “001” as the setting value before the change and “002” as the setting value after the change.

Subsequently, in “S13” shown in FIG. 7B, “003” is input in the setting information #2 as the setting value after the change. As the screen setting value information, “002” is continuously displayed as the setting value after the change in the setting information #1, “003” is displayed as the setting value after the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 7B, the background color of the setting value after the change is gray. For example, as the display state of the buttons, the executable state of the undo button is continuously displayed so as to indicate that the undo operation can be executed, and the unexecutable state of the redo button is continuously displayed so as to indicate that the redo operation cannot be executed. In such a case, in “S13” of FIG. 7A, the setting information #2 is stored into the undo data storage table. In such a case, the setting value related information of the setting information #2 stored in the undo data storage table includes “002” as the setting value before the change and “003” as the setting value after the change.

Subsequently, in “S14” shown in FIG. 7B, the undo button is pressed. As the screen setting value information, “002” is continuously displayed as the setting value after the change in the setting information #1, “002” is displayed as the setting value before the change in the setting information #2, and “003” is continuously displayed as the setting value before the change in the setting information #3. For example, as the display state of the buttons, the executable state of the undo button is continuously displayed so as to indicate that the undo operation can be executed, and the unexecutable state of the redo button is canceled (that is, a grayed out display of the redo button is canceled) so as to indicate that the redo operation can be executed. In such a case, in “S14” of FIG. 7A, the undo operation for the setting information #2 (that is, an operation of canceling “003” which is the setting value after the change in the setting information #2) is performed. In such a case, the setting information #2 stored in the undo data storage table is stored into the redo data storage table and deleted from the undo data storage table.

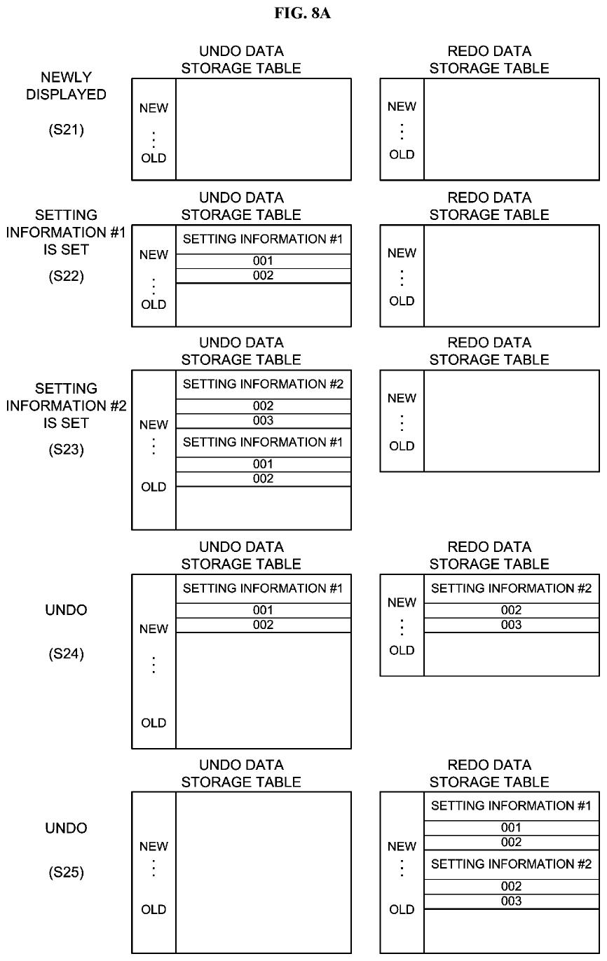

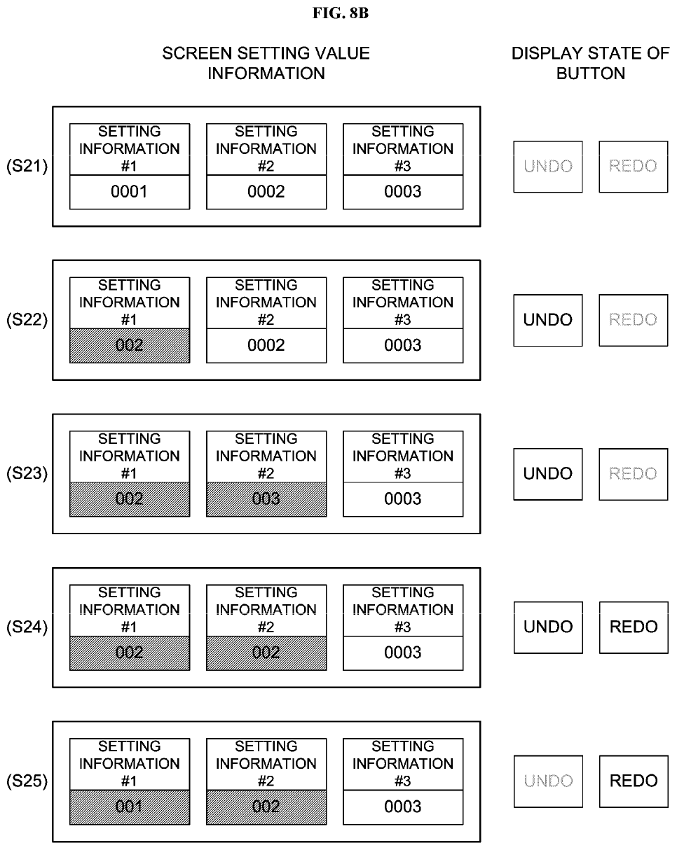

FIG. 8A is a diagram schematically illustrating a transition example of the undo data storage table and the redo data storage table when the undo operation is performed twice after the setting operation for the setting values is performed twice. Further, FIG. 8B is a diagram schematically illustrating an example of the changes of the screen setting value information and an example of the changes of the display state of the undo button and the redo button in accordance with the transition example of the undo data storage table and the redo data storage table shown in FIG. 8A.

In “S21” shown in FIG. 8B, as an example, the recipe edit screen 40 shown in FIG. 4A is newly displayed. In such a case, the setting information #1, the setting information #2 and the setting information #3 are displayed as the screen setting value information shown in “S21” of FIG. 8B. In the setting information #1, “001” is displayed as the setting value before the change. In the setting information #2, “002” is displayed as the setting value before the change. In the setting information #3, “003” is displayed as the setting value before the change. As for the display state of the buttons, both of the undo button and the redo button are displayed (for example, grayed out) indicating that they cannot be executed. In such a case, as shown in “S21” of FIG. 8A, no data is stored in each of the undo data storage table and the redo data storage table.

Subsequently, in “S22” shown in FIG. 8B, “002” is input in the setting information #1 as the setting value after the change. As the screen setting value information, “002” is displayed as the setting value after the change in the setting information #1, “002” is continuously displayed as the setting value before the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 8B, the background color of the setting value after the change is gray. For example, as the display state of the buttons, the unexecutable sate of the undo button is canceled so as to indicate that the undo operation can be executed, and the unexecutable sate of the redo button is continuously displayed so as to indicate that the redo operation cannot be executed. In such a case, in “S22” of FIG. 8A, the setting value related information of the setting information #1 is stored into the undo data storage table. In such a case, the setting value related information of the setting information #1 stored in the undo data storage table includes “001” as the setting value before the change and “002” as the setting value after the change.

Subsequently, in “S23” shown in FIG. 8B, “003” is input in the setting information #2 as the setting value after the change. As the screen setting value information, “002” is continuously displayed as the setting value after the change in the setting information #1, “003” is displayed as the setting value after the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 8B, the background color of the setting value after the change is gray. For example, as the display state of the buttons, the executable state of the undo button is continuously displayed so as to indicate that the undo operation can be executed, and the unexecutable state of the redo button is continuously displayed so as to indicate that the redo operation cannot be executed. In such a case, in “S23” of FIG. 8A, the setting information #2 is stored into the undo data storage table. In such a case, the setting information #2 stored in the undo data storage table includes “002” as the setting value before the change and “003” as the setting value after the change.

Subsequently, in “S24” shown in FIG. 8B, the undo button is pressed. As the screen setting value information, “002” is continuously displayed as the setting value after the change in the setting information #1, “002” is displayed as the setting value before the change in the setting information #2, and “003” is continuously displayed as the setting value before the change in the setting information #3. For example, as the display state of the buttons, the executable state of the undo button is continuously displayed so as to indicate that the undo operation can be executed, and the unexecutable state of the redo button is canceled (that is, the grayed out display of the redo button is canceled) so as to indicate that the redo operation can be executed. In such a case, in “S24” of FIG. 8A, the undo operation for the setting information #2 (that is, the operation of undoing (canceling) “003” which is the setting value after the change in the setting information #2) is performed. In such a case, the setting information #2 stored in the undo data storage table is stored into the redo data storage table and deleted from the undo data storage table.

Subsequently, in “S25” shown in FIG. 8B, the undo button is pressed again. As the screen setting value information, “001” is displayed as the setting value before the change in the setting information #1, “002” is continuously displayed as the setting value before the change in the setting information #2, and “003” is continuously displayed as the setting value before the change in the setting information #3. For example, as the display state of the buttons, the executable state of the undo button is canceled (that is, the unexecutable state of the undo button is displayed (for example, grayed out)) so as to indicate that the undo operation cannot be executed, and the executable state of the redo button is continuously displayed so as to indicate that the redo operation can be executed. In such a case, in “S25” of FIG. 8A, the undo operation for the setting information #1 (that is, an operation of undoing (canceling) “002” which is the setting value after the change in the setting information #1) is performed. In such a case, the setting information #1 stored in the undo data storage table is stored into the redo data storage table and deleted from the undo data storage table.

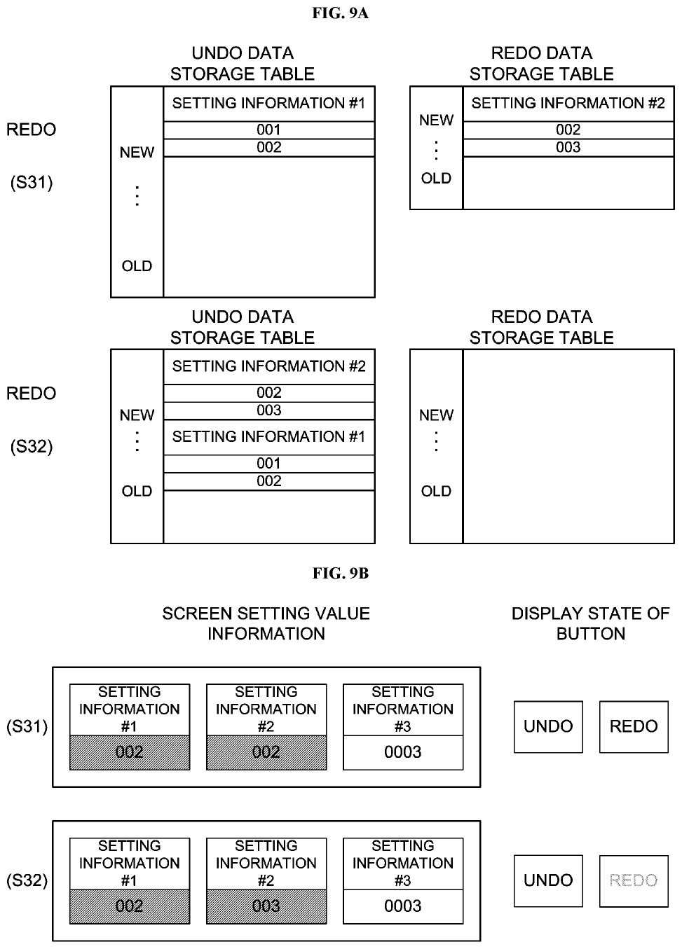

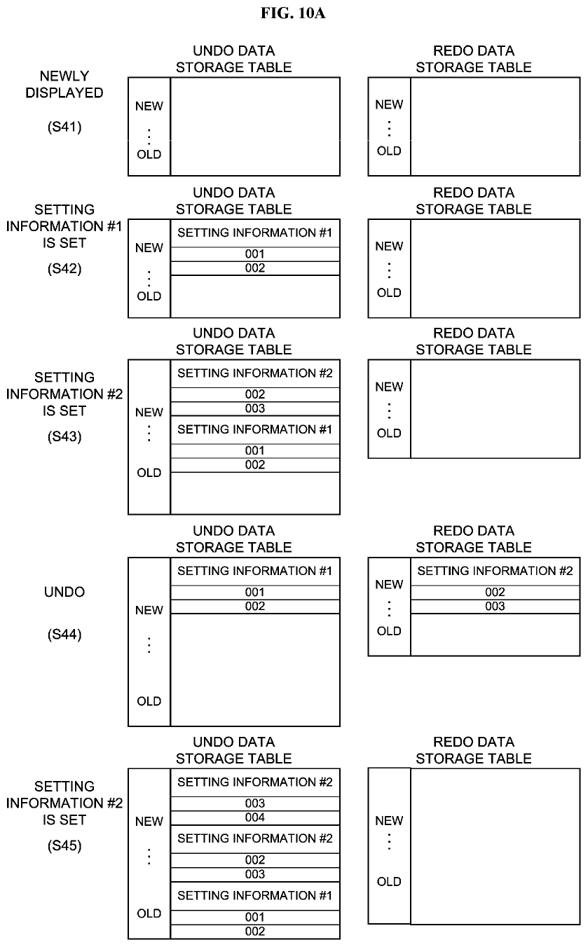

FIG. 9A is a diagram schematically illustrating a transition example of the undo data storage table and the redo data storage table when the redo operation is further performed twice following the transition example of FIG. 8A. Further, FIG. 9B is a diagram schematically illustrating an example of the changes of the screen setting value information and an example of the changes of the display state of the undo button and the redo button in accordance with the transition example of the undo data storage table and the redo data storage table shown in FIG. 9A.

Subsequently, in “S31” shown in FIG. 9B, the redo button is pressed. As the screen setting value information, “002” is displayed as the setting value after the change in the setting information #1, “002” is continuously displayed as the setting value before the change in the setting information #2, and “003” is continuously displayed as the setting value before the change in the setting information #3. For example, as the display state of the buttons, the unexecutable state of the undo button is canceled (that is, a grayed out display of the undo button is canceled) so as to indicate that the undo operation can be executed, and the executable state of the redo button is continuously displayed so as to indicate that the redo operation can be executed. In such a case, in “S31” of FIG. 9A, the redo operation for the setting information #1 (that is, an operation of redoing (resetting) “002” which is the setting value after the change in the setting information #1) is performed. In such a case, the setting information #1 stored in the redo data storage table is stored into the undo data storage table and deleted from the redo data storage table.

Subsequently, in “S32” shown in FIG. 9B, the redo button is pressed again. As the screen setting value information, “002” is continuously displayed as the setting value after the change in the setting information #1, “003” is displayed as the setting value after the change in the setting information #2, and “003” is continuously displayed as the setting value before the change in the setting information #3. For example, as the display state of the buttons, the executable state of the undo button is continuously displayed so as to indicate that the undo operation can be executed, and the executable state of the redo button is canceled (that is, the unexecutable state of the redo button is displayed (for example, grayed out)) so as to indicate that the redo operation cannot be executed. In such a case, in “S32” of FIG. 9A, the redo operation for the setting information #2 (that is, an operation of redoing (resetting) “003” which is the setting value after the change in the setting information #2) is performed. In such a case, the setting information #2 stored in the redo data storage table is stored into the undo data storage table and deleted from the redo data storage table.

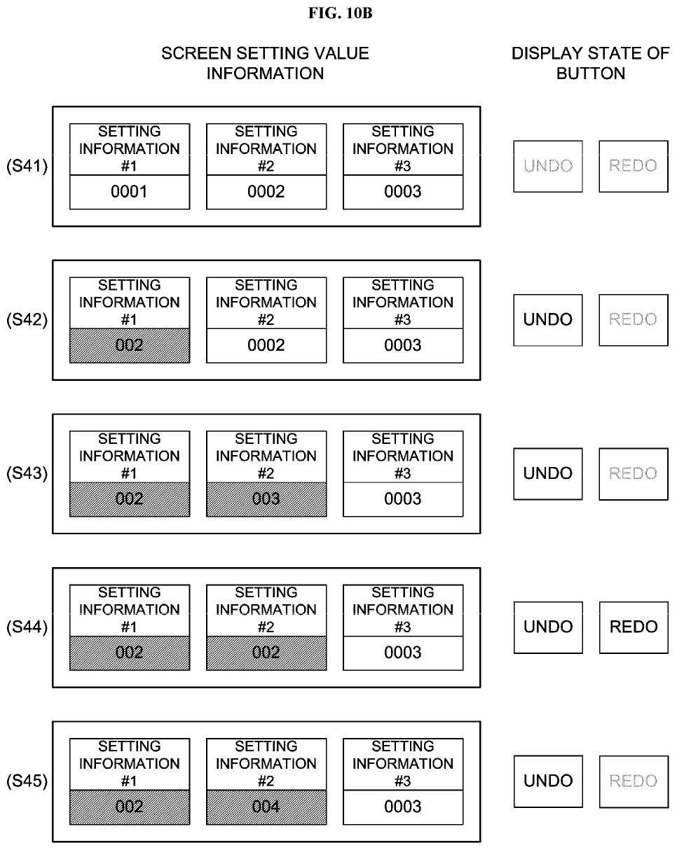

FIG. 10A is a diagram schematically illustrating a transition example of the undo data storage table and the redo data storage table when the setting operation for the setting values is performed twice, the undo operation is performed once and then the setting operation for the setting values is further performed once. Further, FIG. 10B is a diagram schematically illustrating an example of the changes of the screen setting value information and an example of the changes of the display state of the undo button and the redo button in accordance with the transition example of the undo data storage table and the redo data storage table shown in FIG. 10A.

In “S41” shown in FIG. 10B, as an example, the recipe edit screen 40 shown in FIG. 4A is newly displayed. In such a case, the setting information #1, the setting information #2 and the setting information #3 are displayed as the screen setting value information shown in “S41” of FIG. 10B. In the setting information #1, “001” is displayed as the setting value before the change. In the setting information #2, “002” is displayed as the setting value before the change. In the setting information #3, “003” is displayed as the setting value before the change. As for the display state of the buttons, both of the undo button and the redo button are displayed (for example, grayed out) indicating that they cannot be executed. In such a case, as shown in “S41” of FIG. 10A, no data is stored in each of the undo data storage table and the redo data storage table.

Subsequently, in “S42” shown in FIG. 10B, “002” is input in the setting information #1 as the setting value after the change. As the screen setting value information, “002” is displayed as the setting value after the change in the setting information #1, “002” is continuously displayed as the setting value before the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 10B, the background color of the setting value after the change is gray. For example, as the display state of the buttons, the unexecutable sate of the undo button is canceled so as to indicate that the undo operation can be executed, and the unexecutable sate of the redo button is continuously displayed so as to indicate that the redo operation cannot be executed. In such a case, in “S42” of FIG. 10A, the setting value related information of the setting information #1 is stored into the undo data storage table. In such a case, the setting value related information of the setting information #1 stored in the undo data storage table includes “001” as the setting value before the change and “002” as the setting value after the change.

Subsequently, in “S43” shown in FIG. 10B, “003” is input in the setting information #2 as the setting value after the change. As the screen setting value information, “002” is continuously displayed as the setting value after the change in the setting information #1, “003” is displayed as the setting value after the change in the setting information #2, and “003” is continuously displayed as the setting value before the change in the setting information #3. For example, the display color of the setting value after the change may be switched to the background color different from that of the setting value before the change. For example, the display characters of the setting value after the change may be changed by switching the display color of the display characters. For example, in FIG. 10B, the background color of the setting value after the change is gray. For example, as the display state of the buttons, the executable state of the undo button is continuously displayed so as to indicate that the undo operation can be executed, and the unexecutable state of the redo button is continuously displayed so as to indicate that the redo operation cannot be executed. In such a case, in “S43” of FIG. 10A, the setting information #2 is stored into the undo data storage table. In such a case, the setting value related information of the setting information #2 stored in the undo data storage table includes “002” as the setting value before the change and “003” as the setting value after the change.

Subsequently, in “S44” shown in FIG. 10B, the undo button is pressed. As the screen setting value information, “002” is continuously displayed as the setting value after the change in the setting information #1, “002” is displayed as the setting value before the change in the setting information #2, and “003” is continuously displayed as the setting value before the change in the setting information #3. For example, as the display state of the buttons, the executable state of the undo button is continuously displayed so as to indicate that the undo operation can be executed, and the unexecutable state of the redo button is canceled (that is, the grayed out display of the redo button is canceled) so as to indicate that the redo operation can be executed. In such a case, in “S44” of FIG. 10A, the undo operation for the setting information #2 (that is, the operation of canceling “003” which is the setting value after the change in the setting information #2) is performed. In such a case, the setting information #2 stored in the undo data storage table is stored into the redo data storage table and deleted from the undo data storage table.

Subsequently, in “S45” shown in FIG. 10B, “004” is input in the setting information #2 as the setting value after the change. As the screen setting value information, “002” is continuously displayed as the setting value after the change in the setting information #1, “004” is displayed as the setting value after the change in the setting information #2, and “003” is continuously displayed as the setting value before the change in the setting information #3. For example, as the display state of the buttons, the executable state of the undo button is continuously displayed so as to indicate that the undo operation can be executed, and the unexecutable state of the redo button is displayed (for example, grayed out) so as to indicate that the redo operation cannot be executed. In such a case, in “S45” of FIG. 10A, an entirety of the setting value related information stored in the redo data storage table is stored into the undo data storage table, and the redo data storage table is cleared. Thereafter, new setting information #2 is stored into the undo data storage table. In such a case, the new setting information #2 stored in the undo data storage table includes “003” as the setting value before the change and “004” as the setting value after the change.

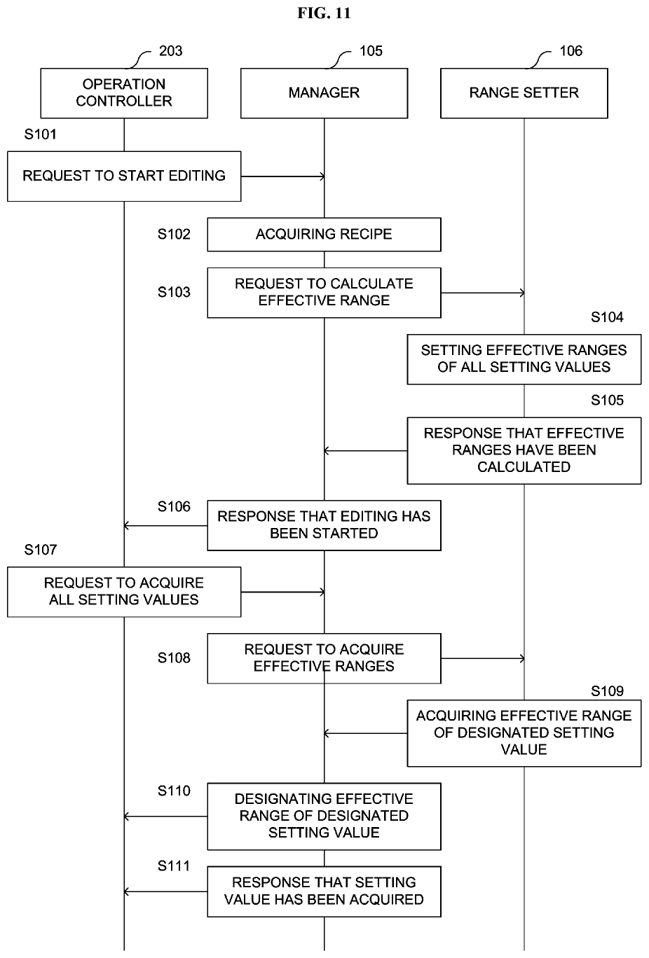

Subsequently, the operation of the substrate processing apparatus 1 according to the present embodiments will be described with reference to FIGS. 11 through 14.

FIG. 11 is a sequence diagram schematically illustrating an example of an edit starting process according to the present embodiments.

In a step S101 of FIG. 11, the operation controller 203 sends an edit start request to start editing the setting value to the manager 105.

In a step S102, the manager 105 acquires the recipe file from the memory 103 in response to the edit start request from the operation controller 203.

In a step S103, the manager 105 sends a calculation request to calculate the effective range of the setting value to the range setter 106.

In a step S104, the range setter 106 sets (or calculates) the effective ranges of the entirety of the setting values in response to the calculation request from the manager 105.

In a step S105, the range setter 106 returns to the manager 105 a response indicating that the effective ranges of the entirety of the setting values have been calculated.

In a step S106, the manager 105 returns to the operation controller 203 a response indicating that that the editing has been started.

In a step S107, the operation controller 203 sends an acquisition request to acquire the entirety of the setting values to the manager 105.

In a step S108, the manager 105 sends the acquisition request to acquire the effective ranges of the entirety of the setting values to the range setter 106.

In a step S109, the range setter 106 acquires the effective range of the designated setting value in response to the acquisition request from the manager 105 and sends the effective range of the designated setting value to the manager 105.

In a step S110, the manager 105 designates the effective range of the designated setting value with respect to the operation controller 203.

In a step S111, the manager 105 returns to the operation controller 203 a response indicating that the acquisition of the setting value has been performed. Thereby, a series of processing is terminated.

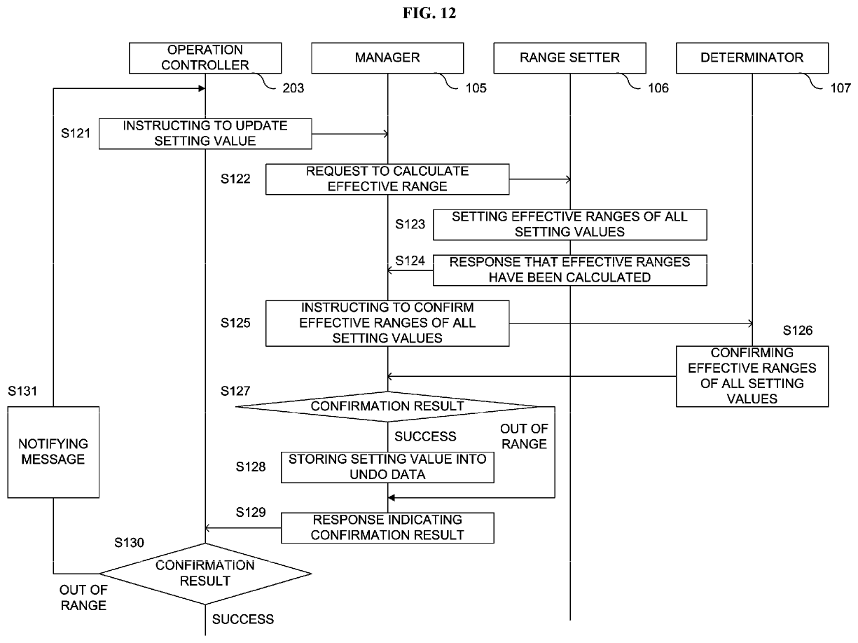

FIG. 12 is a sequence diagram schematically illustrating an example of a setting value changing process according to the present embodiments.

In step a S121 of FIG. 12, the operation controller 203 instructs the manager 105 to update the setting value.

In a step S122, the management unit 105 sends a calculation request to calculate the effective range of the setting value to the range setter 106 in response to an update instruction from the operation controller 203.

In a step S123, the range setter 106 sets the effective ranges of the entirety of the setting values in response to the calculation request from the manager 105.

In a step S124, the range setter 106 returns to the manager 105 a response indicating that the effective ranges of the entirety of the setting values have been calculated.

In a step S125, the manager 105 instructs the determinator 107 to confirm (or check) the effective ranges of the entirety of the setting values.

In a step S126, the determinator 107 confirms the effective ranges of the entirety of the setting values in response to an instruction from the manager 105 and sends a confirmation result to the manager 105.

In a step S127, the manager 105 determines whether or not the setting value is within the effective range based on the confirmation result from the determinator 107. When it is determined that the setting value is within the effective range (“SUCCESS” in “S127” of FIG. 12), a step S128 is performed. When it is determined that the setting value is out of the effective range (“OUT OF RANGE” in “S127” of FIG. 12), a step S129 is performed.

In the step S128, the manager 105 stores the setting values in the undo data storage table.

In the step S129, the manager 105 returns to the operation controller 203 a response indicating the confirmation result of the setting value.

In a step S130, the operation controller 203 determines whether or not the setting value is within the effective range based on the confirmation result from manager 105. When it is determined that the setting value is within the effective range (“SUCCESS” in “S130” of FIG. 12), the setting value changing process is terminated as it is. When it is determined that the setting value is out of the effective range (“OUT OF RANGE” in “S130” of FIG. 12), a step S131 is performed.

In the step S131, the operation controller 203 notifies the display 204 that the setting value is out of the effective range, and the step S121 is performed again to repeatedly perform the setting value changing process.

According to the present embodiments, when inputting the setting value, a presence or absence of the setting value related information is checked from the redo data storage table. When there is the setting value related information in the redo data storage table, the entirety of the setting value related information is stored into the undo data storage table. Then, the setting value related information related to the setting value input as describe above is stored into the undo data storage table, and the redo data storage table is cleared.

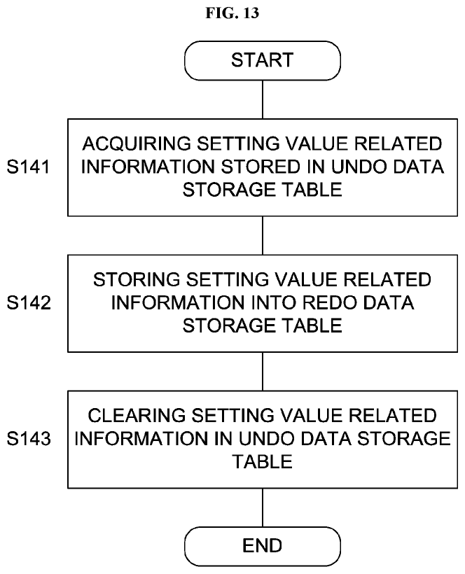

FIG. 13 is a flow chart schematically illustrating an exemplary process flow of an undo operation process according to the present embodiments.

In a step S141 of FIG. 13, the CPU 101 acquires the latest setting value related information stored in the undo data storage table.

In a step S142, the CPU 101 stores the setting value related information acquired in the step S141 into the latest position of the redo data storage table.

In a step S143, the CPU 101 clears the latest setting value related information stored in the undo data storage table. Thereby, a series of processing is terminated.

That is, in a case of the undo operation, the setting value related information stored in the undo data storage table is acquired, and the setting value related information acquired as described above is stored into the redo data storage table. Then, the setting value related information stored in the undo data storage table is cleared. In such a case, the effective ranges of the entirety of the setting values are recalculated, and the effective ranges of the entirety of the setting values recalculated as described above are determined again. Further, a determination result of the effective ranges recalculated as described above is reflected.

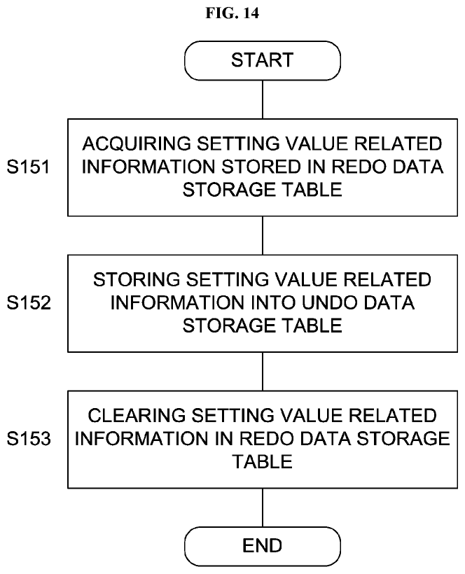

FIG. 14 is a flow chart schematically illustrating an exemplary process flow of a redo operation process according to the present embodiments.

In a step S151 of FIG. 14, the CPU 101 acquires the latest setting value related information stored in the redo data storage table.

In a step S152, the CPU 101 stores the setting value related information acquired in the step S151 into the latest position of the undo data storage table.

In a step S153, the CPU 101 clears the latest setting value related information stored in the redo data storage table. Thereby, a series of processing is terminated.

That is, in a case of the redo operation, the setting value related information stored in the redo data storage table is acquired, and the setting value related information acquired as described above is stored into the undo data storage table. Then, the setting value related information stored in the redo data storage table is cleared. In such a case, the effective ranges of the entirety of the setting values are recalculated, and the effective ranges of the entirety of the setting values recalculated as described above are determined again. Further, a determination result of the effective ranges recalculated as described above is reflected.

As described above, according to the present embodiments, by recalculating the input range and performing the range check for the entirety of the edit items when the setting value is changed, it is possible to always maintain the consistency of the edit items, and it is also possible to reduce the wasted time for re-editing the file due to the file inconsistency when executing the substrate processing. As a result, it is possible to contribute to improving the production efficiency.

In addition, by confirming the effective range for the entirety of the edit items when the edit items are set, it is possible to clarify the items to be corrected, and thereby, it is possible to contribute to the efficiency of editing the file. As a result, it is possible to contribute to improving the work efficiency.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof. For example, the substrate processing apparatus 1 according to the embodiments described above is described above as an example. However, the technique of the present disclosure may also be applied to a program that causes a computer to perform the functions of the substrate processing apparatus 1. Further, the technique of the present disclosure may also be applied to a non-transitory computer-readable recording medium storing the program that causes the computer to perform the functions of the substrate processing apparatus 1.

In addition, the configuration of the substrate processing apparatus 1 described in the embodiments described above is merely an example, and may be changed in accordance with circumstances without departing from the scope of the technique of the present disclosure.

In addition, the process flow of the program described in the embodiments described above is merely an example, and may be changed. For example, an unnecessary step may be deleted, a new step may be added, or a process sequence may be changed without departing from the scope of the technique of the present disclosure.

For example, the embodiments described above are described by way of an example in which the processing according to the embodiments is implemented by a software configuration that uses the computer to execute the program. However, the technique of the present disclosure is not limited thereto. For example, the technique of the present disclosure may also be applied to a hardware configuration capable of performing the processing, or may also be applied to a combination of hardware and software configuration capable of performing the processing.

For example, the embodiments described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates at a time is used to form the film. For example, the embodiments described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process sequences and the process conditions of each process using the substrate processing apparatuses exemplified above may be substantially the same as those of the embodiments described above. Even in such a case, it is possible to obtain substantially the same effects as in the embodiments described above.

According to some embodiments of the present disclosure, it is possible to efficiently perform the editing operation for the file while ensuring the consistency of the setting values before and after the change.

What is claimed is:

1. A substrate processing apparatus comprising:
a display configured to display a file describing substrate processing conditions containing a plurality of setting values;
an operation controller configured to perform an editing operation for the file and to perform at least one operation of an undo operation or a redo operation for a setting value among the plurality of setting values, wherein the setting value is set in the editing operation;
a controller configured to be capable of controlling an editing operation for the setting value, wherein the controller comprises:
a memory configured to store the file and operation history information on the undo operation or the redo operation; and
a determinator configured to determine whether or not the setting value is within an effective range when the setting value is reset during the undo operation or the redo operation; and
a process vessel in which a substrate is processed based on the file stored in the memory.

2. The substrate processing apparatus of claim 1, wherein the controller further comprises a manager configured to manage the setting value,
wherein the manager is configured to search for information on the setting value in accordance with an instruction from the operation controller.

3. The substrate processing apparatus of claim 2, wherein the controller further comprises a range setter configured to set an upper limit value and a lower limit value of the effective range of the setting value,
wherein the range setter is configured to set effective ranges of an entirety of the setting values in accordance with an instruction from the manager.

4. The substrate processing apparatus of claim 3, wherein the range setter is configured to check a range setting condition set in advance for each item and setting information for another item related thereto to calculate the upper limit value and the lower limit value.

5. The substrate processing apparatus of claim 1, wherein the determinator is configured to determine whether or not every one of the setting values defined in the file remains within an effective range when the setting value is changed.

6. The substrate processing apparatus of claim 5, wherein the controller is further configured to be capable of notifying the operation controller that the setting value is out of the effective range when a determination result of the determinator is that the setting value is out of the effective range.

7. The substrate processing apparatus of claim 6, wherein the operation controller is further configured to be capable of instructing the display to display that there is at least one setting value out of the effective range in accordance with a notification from the controller.

8. The substrate processing apparatus of claim 7, wherein the display is further configured to display the notification that the setting value is out of the effective range in accordance with an instruction from the operation controller, and is further configured to switch a display of a target setting value in accordance with the instruction from the operation controller.

9. The substrate processing apparatus of claim 1, wherein the display is provided with a button for the undo operation or the redo operation.

10. The substrate processing apparatus of claim 9, wherein the display is further configured to switch display characters of the button in accordance with a display language of the display.

11. The substrate processing apparatus of claim 9, wherein the display is further configured to switch a display of the button in accordance with the undo operation or the redo operation.

12. The substrate processing apparatus of claim 1, wherein the operation history information comprises:
first operation history information configured to store setting value related information of the setting value; and
second operation history information configured to store the setting value related information as an undo history when the undo operation is executed.

13. The substrate processing apparatus of claim 12, wherein the setting value related information comprises at least one among setting items, the setting value before a change and the setting value after a change.

14. The substrate processing apparatus of claim 12, wherein the controller is further configured to be capable of, when executing the undo operation, storing the setting value related information of the first operation history information into the second operation history information and capable of deleting the setting value related information stored in the first operation history information.

15. The substrate processing apparatus of claim 12, wherein the controller is further configured to be capable of, when executing the redo operation, storing the setting value related information of the second operation history information into the first operation history information and capable of deleting the setting value related information stored in the second operation history information.

16. The substrate processing apparatus of claim 12, wherein the controller is further configured to be capable of, when acquiring new setting value related information, storing the setting value related information of the second operation history information into the first operation history information and capable of storing the new setting value related information into the first operation history information.

17. The substrate processing apparatus of claim 16, wherein the controller is further configured to be capable of clearing the second operation history information.

18. The substrate processing apparatus of claim 1, wherein the controller is further configured to be capable of clearing the operation history information when the editing operation for the file is completed.

19. A method of manufacturing a semiconductor device, comprising:
(a) displaying a file describing substrate processing conditions containing a plurality of setting values;
(b) performing at least one operation of an undo operation or a redo operation for a setting value among the plurality of setting values when editing the setting value;
(c) storing the file and operation history information on the undo operation or the redo operation;
(d) determining whether or not the setting value is within an effective range when the setting value is reset during the undo operation or the redo operation; and
(e) processing a substrate based on the file stored in (c).

20. A non-transitory computer-readable recording medium storing a program that causes a substrate processing apparatus, by a computer, to perform:
(a) displaying a file describing substrate processing conditions containing a plurality of setting values;
(b) performing at least one operation of an undo operation or a redo operation for a setting value among the plurality of setting values when editing the setting value;
(c) storing the file and operation history information on the undo operation or the redo operation;
(d) determining whether or not the setting value is within an effective range when the setting value is reset during the undo operation or the redo operation; and
(e) processing a substrate based on the file stored in (c).
